(19) United States
(12) Patent Application Publication
(10) Pub. No.: US 2014/0030928 A1
(43) Pub. Date: Jan. 30, 2014

(54) ELECTRICAL CARD CONNECTOR WITH METAL SHELL

(71) Applicant: HON HAI PRECISION INDUSTRY CO., LTD., New Taipei (TW)

(72) Inventors: FANG-YUE ZHU, Kunshan (CN); YU-CHE HUANG, New Taipei (TW); JIN-KUI HU, Kunshan (CN)

(73) Assignee: HON HAI PRECISION INDUSTRY CO., LTD., New Taipei (TW)

(21) Appl. No.: 13/949,257

(22) Filed: Jul. 24, 2013

(30) Foreign Application Priority Data
Jul. 25, 2012 (CN) 201220362632.9

(51) Int. Cl. H05K 5/04

(52) U.S. Cl. CPC H05K 5/04
USPC 439/629

(57) ABSTRACT

An electrical card connector includes an insulative housing, a plurality of the contacts received in the insulative housing and a metal shell covering the insulative housing. The insulative housing has a receiving cavity receiving a first and a second electrical cards. The contacts include a plurality of first contacts connecting with the first electrical card and a plurality of second contacts combining with the first contacts to contact with the second electrical card. The metal shell has at least one elastic arm extending into the receiving cavity and contacting with a pad of the second electrical card but not contacting with a pad of the first electrical card to instead of a grounding contact of an electrical connector of prior art. It would reduces the number of the contacts to make the structure of the contact easy.

### BACKGROUND OF THE INVENTION

1. Field of the invention

The present invention generally relates to an electrical card connector and more particularly to an electrical card connector with a metal shell.

2. Description of Related Art

Electrical cards are known in the art and contain intelligence in the form of a memory circuit or other electronic program. Some form of card readers retrieve the information or data stored on the card. Such cards are used in many applications in today's electronic society, such as video cameras, digital cameras, smart phones, PDAs, music players, ATMs, cable television decoders, toys, games, PC adapters, multi-media cards and other electronic applications, etc.

U.S. Patent Application Publication No. 2012252276 discloses an electrical card connector used for receiving a first electrical card and a second electrical card which is different from the electrical card. The first electrical card connector comprises an insulative housing and a plurality contacts retained in the insulative housing. The contacts include a first group of contacts and a second group of contacts, the first group of contacts have a plurality of first contacts and the second group of contacts have a plurality of second contacts. The second contacts are combined with the first contacts to contact with the electrical card. The first and second contacts each include a retaining portion retained in the insulative housing, a contacting portion and a soldering portion extending out of the insulative housing. Some of the first contacts and the second contacts are publicly used are soldering portion. But, the contacts have a large amount and they are assigned closed with each other nearly. It will improve the manufactured difficultly.

So, an improved connector is needed.

### SUMMARY OF THE INVENTION

The present invention provides an electrical card connector used for connecting with a first electrical card and a second electrical card. The electrical card connector comprises an insulative housing, a plurality contacts retained in the insulative housing and a metal shell covering the insulative housing. The insulative housing has an receiving cavity for receiving the first and second electrical cards. The contacts have a first group of contacts connecting with the first electrical card and a second group of contacts combining with the second group of contacts connecting with the second electrical card. The first and second groups of contacts are arranging from front to rear along an inserting direction of the electrical card. The metal shell has at least an elastic arm extending into the receiving cavity and contacting with the second electrical card but not contacting with the first electrical card.

Other objects, advantages and novel features of the present invention will become more apparent from the following detailed description of the present embodiment when taken in conjunction with the accompanying drawings.

### BRIEF DESCRIPTION OF THE DRAWINGS

FIG. 1 is an assembled perspective view of an electrical card connector according to a preferred embodiment of the present invention, showing an electrical card inserted in the electrical card connector;

FIG. 2 is another perspective view of the electrical card connector and the electrical card as shown in FIG. 1;

FIG. 3 is a partially exploded view of the electrical card connector according to a preferred embodiment of the present invention;

FIG. 4 is an exploded view of the electrical card connector as shown in FIG. 3.

### DETAILED DESCRIPTION OF THE INVENTION

Reference will now be made to the drawing figures to describe the preferred embodiment of the present invention in detail.

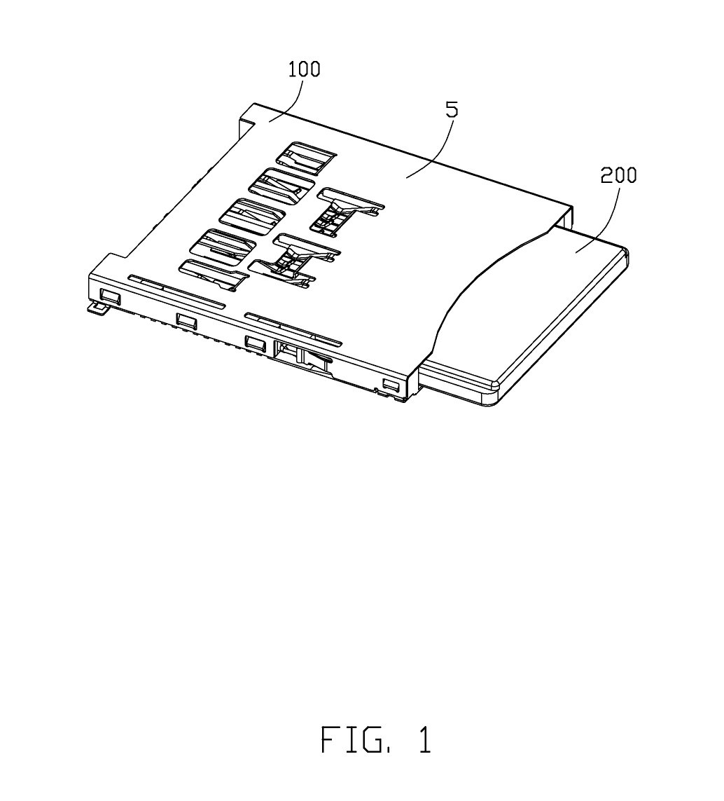

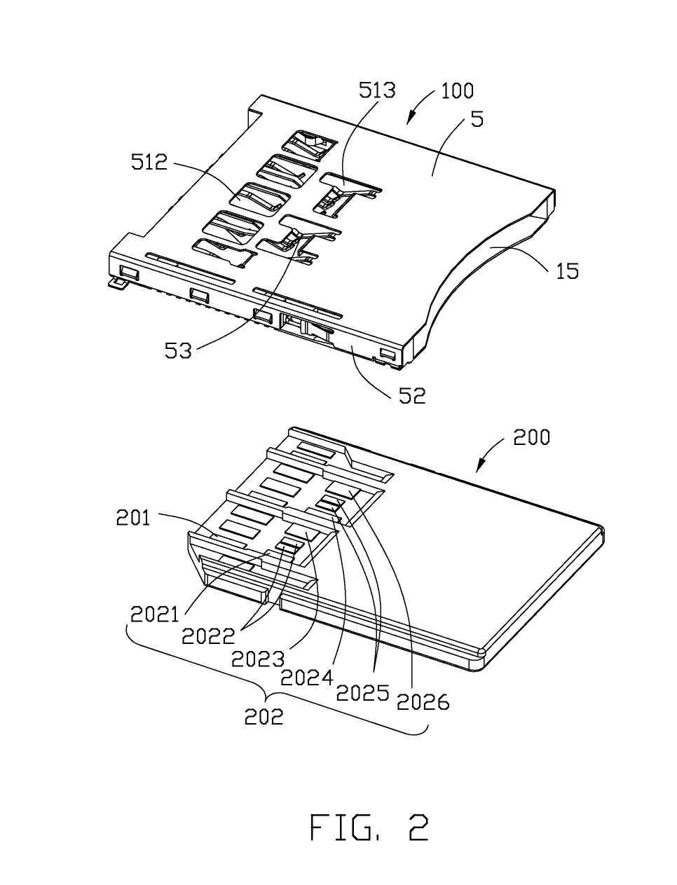

Referring to FIGS. 1-3, an electrical card connector 100 is used for receiving a first electrical card (not shown) and a second electrical card 200 which is different from the first electrical card. The first electrical card is a SD (Secure Digital) card. The second electrical card 200 includes a plurality of first pads 201 arranged in a first row and a plurality of second pads 202 arranged in a second row parallel to the first row along a mating direction. The first pads 201 are same as that of the SD card. The second pads 202 include eight contacting pads including a first grounding pad 2021, two first signal pads 2022, a second grounding pad 2023, a power pad 2024, two second signal pads 2025 and third grounding pad 2026 along the left to right direction.

The electrical card connector 100 comprises an insulative housing 1, a plurality of contacts 2 retained in the insulative housing 1, an ejector 3 assembled in the insulative housing 1, a switch contact 4 and a shield metal shell 5.

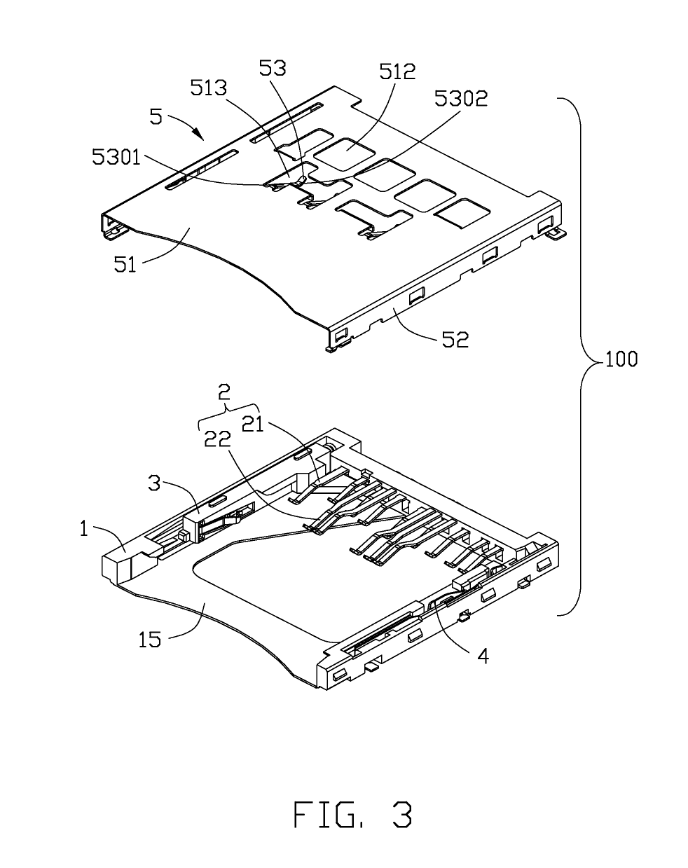

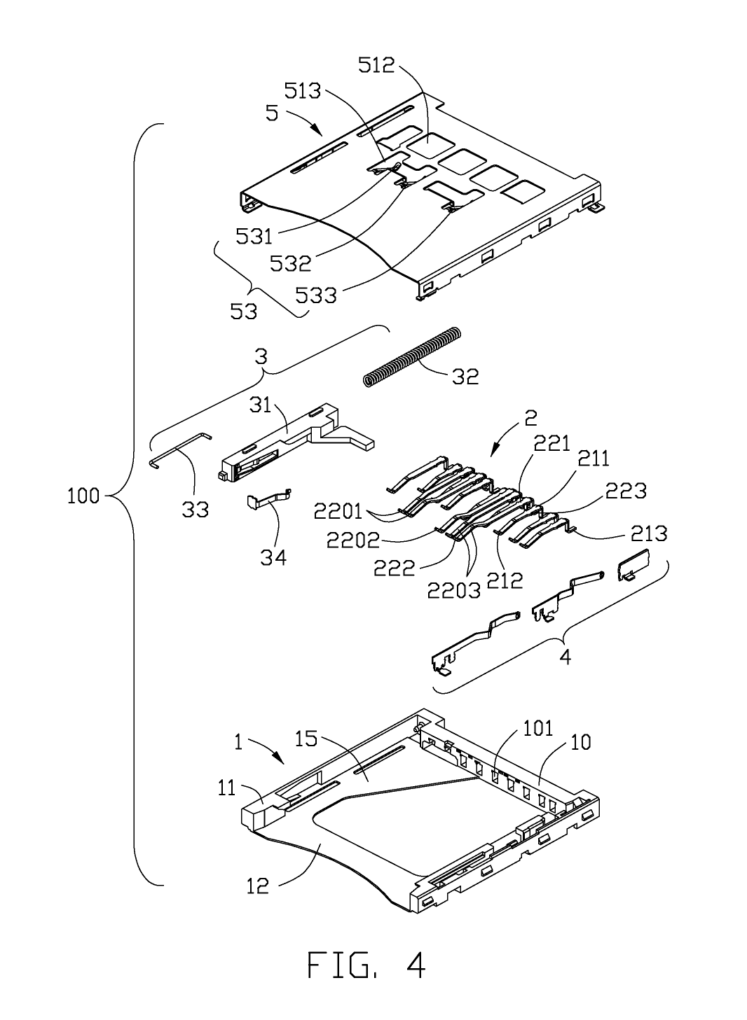

Referring to FIGS. 3-4, the insulative housing 1 includes a base portion 10, two side portions 11 extending forwardly from two sides of the base portion 10, a bottom wall 12 connecting the two side portions 11 and a receiving cavity 15 surrounding by the base portion 10, the bottom wall 12 and the side portion 11. The receiving cavity 15 is used for receiving the first electrical card (not shown) and the second electrical card 200. The base portion 10 has a plurality of mounting slots 101 passing therethrough along a front to rear direction.

The contacts 2 include a first group of contacts and a second group of contacts, the first group of contacts are used for contacting with the first electrical card (not shown). The first group of contacts is combining with the second groups to contact with the second electrical card 200. The first group of contacts include a plurality of first contacts 21 and the second group of contacts include a plurality of second contacts 22. The first contacts 21 each include a first retaining portion 211 retained in the insulative housing 1, a first contacting portion 212 extending forwardly from the retaining portion 211 and into the receiving cavity 15 and a first soldering portion 213 extending backwardly from the first retaining portion 211 and out of the insulative housing 1. The second contacts 22 each include a second retaining portion 221 retained in the insulative housing 1, a second contacting portion 222 extending forwardly from the retaining portion 221 and into the receiving cavity 15 and a second soldering portion 223 extending backwardly from the second retaining portion 221 and out of the insulative housing 1. The second contacting portion 222 exrtends forwardly beyond the first contacting portion 212. The first and second contacting portions 212, 222 are located in a same height. A width of the first soldering portion 213 is same as that of the second soldering portion 223. The first and second soldering portions 213, 223 are arranged in one row behind the base portion 10 and along the left to right direction. The second contacts include two first signal contacts 2201, a power contact 2202 and two second signal contacts 2203 along the left to right direction. When the second electrical card 200 is inserted into the receiving cavity 15, the first signal contact 2201 contacts with the first signal pad 2022 of the second electrical card 200, the power contact 2202 contacts with the power pad 2024 and the second signal contact 2203 contacts with the second signal pad 2025 to which the grounding pads 2021, 2023, 2026 contact will be described in below.

Referring to FIG. 4, the ejector 3 is assembled to one side of the side portions 11. The ejector 3 includes a slider 31, a spring 32, a guiding post 33 and an elastic plate 34 assembled in the slider 31 and used for locking the first and second electrical cards.

The metal shell 5 includes a top wall 51 and two side walls 52 extending downwardly from two sides of the top wall 51. The top wall 51 has a first opening 512 corresponding to the first and second contacting portions 212, 222 along an upper to down direction and a second opening 513 located in a front of the first opening 51. When the second electrical card 200 inserts into the receiving cavity 15, the electrical card 200 resists the first and second contacting portions 212, 222 upwardly, the first and second opening 512, 513 is supplied a swing space to avoid the first and second contacting portion 212, 222 contacting with the top wall 51 of the metal shell 5.

The two side walls 52 lock with the side portions 11 of the insulative housing 1. The second opening 513 has a plurality of the elastic arms 53 extending rearward from a front edge thereof The elastic arms 53 have a first elastic arm 531, a second arm 532 and a third arm 533 arranged along the left to right direction. The first elastic arm 531 is located in the left of the first signal contact 2201, the second elastic arm 532 is located between the first signal contact 2201 and the power contact 2202 and the third contact 2203 is located in the right of a right one of the two second signal contacts 2203.

The elastic arms 53 each has an extending portion 5301 extending from the second opening 513 and into the receiving cavity 15, a resisting portion 5302 extending upwardly from a rear end of the extending portion 5301. The resisting portions 5302 are located in the receiving cavity 15 and arranged one row with the second contacts 22. The first elastic arm 531 contacts with the first grounding pad 2201 of the second electrical card 200 for grounding. The second elastic arm 532 contacts with the second grounding pad 2023 of the second electrical card 200 for grounding. The third elastic arm 533 contacts with the third grounding pad 2026 for grounding.

The electrical card connector 100 has the metal shell 5. The metal shell 5 is formed with a plurality of elastic arms 53 contacting with the first, second and third grounding pads 2021, 2023, 2026, respectively for grounding to instead of a plurality of grounding contacts of an electrical card connector of prior art. It would reduces the number of the contacts to make the structure of the contacts easy.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical card connector used for connecting with an electrical card, comprising:
an insulative housing having a receiving cavity for receiving the electrical card;
a plurality contacts retained in the insulative housing, the contacts having a first group of contacts including a plurality of first contacts and a second group of contacts including a plurality of second contacts and combined with the first group of contacts for connecting with the electrical card, each first contact formed with a first contacting portion located at a first row, each second contact formed with a second contacting portion located in a second row;
a metal shell covering the insulative housing and having at least one elastic arm extending into the receiving cavity and having a resisting portion arranged in the second row same as the second contacting portions of the second contacts.

2. The electrical card connector as claimed in claim 1, wherein the electrical card has a plurality of first contacting pads and a plurality of second contacting pads, the second contacting pads are located in a front of the first contacting pads, the second contacts and the elastic arm contact with the second contacting pads.

3. The electrical card connector as claimed in claim 2, wherein the second contacting pads include a first grounding pad, two first signal pads, a second grounding pad, a power pad, two second signal pads and a third grounding pad, the second group of contacts include two first signal contacts contacting with the first signal pads, a power contact contacting with the power pad and two second signal contacts contacting with the second signal pads.

4. The electrical card connector as claimed in claim 3, wherein the at least one elastic arm include a first elastic arm contacting with the first grounding pad, a second elastic arm contacting with the second grounding pad and a third elastic arm contacting with the third grounding pad.

5. The electrical card connector as claimed in claim 4, wherein the first contact has a first retaining portion retained in the insulative housing, a first contacting portion extending forwardly from the first retaining portion and into the receiving cavity, the second contact has a second retaining portion retained in the insulative housing, the second contacting portion extending forwardly from the second retaining portion and into the receiving cavity, the first contacting portion is located behind the second contacting portion in the second row and the first contacting portion is in a same height as that of the second contacting portion.

6. The electrical card connector as claimed in claim 5, wherein the first contact has a first soldering portion extending backwardly from the first retaining portion and out of the insulative housing, the second contact has a second soldering portion extending backwardly from the second retaining portion and out of the insulative housing, the first and second soldering portions are arranged in one row.

7. The electrical card connector as claimed in claim 5, wherein the metal shell has a top wall covering the insulative housing, the top wall has a first opening and a second opening corresponding to the first and second contacting portions to avoid the first and second contacting portions to contact with the top wall.

8. The electrical card connector as claimed in claim 7, wherein the elastic arms each have an extending portion extending from a edge of the second opening, the resisting portion extends upwardly from a rear of the extending portion and into the receiving cavity.

9. The electrical card connector as claimed in claim 8, wherein the resisting portions and the second contacting portion are located at a same height.

10. The electrical card connector as claimed in claim 5, wherein the insulative housing includes a base portion and two side portions extending forwardly from the base portion, the receiving cavity is surrounded by the base portion and the side portions, the first contacting portion is much closed to the base portion than the second contacting portion.

11. The electrical card connector as claimed in claim 2, wherein the electrical card connector is also used for receiving another electrical card, Secure Digital Memory Card, which only electrically with the first contacts.

12. An electrical card connector, adapter for receiving a first electrical card and a second electrical card, comprising:
an insulative housing having a receiving cavity;
a plurality of contacts having a plurality of first contacts and a plurality of second contact; and
a metal shell having a top wall covering the insulative housing, the top wall having at least one elastic arm extending into the receiving cavity; wherein the second electrical card has a plurality first contacting pads contacting with the first contacts and a plurality of second contacting pads partly contacting with the second contact, and the at least one elastic arm respectively.

13. The electrical connector as claimed in claim 12, wherein the second contacting pads include a first grounding pad, two first signal pads, a second grounding pad, a power pad, two second signal pads and a third grounding pad, the second contacts include two first signal contacts contacting with the first signal pads, a power contact contacting with the power pad and two second signal contacts contacting with the second signal pads.

14. The electrical connector as claimed in claim 13, wherein the at least one elastic arm has three elastic arms, which contact with the first, second and third grounding pads, respectively.

15. The electrical connector as claimed in claim 12, wherein the top wall has at least one second opening, the at least one elastic arm extends from a front edge of the second opening.

16. The electrical connector as claimed in claim 12, wherein the elastic arm and a face end of the second contact are arranged in same row.

17. An electrical card connector assembly comprising:
an insulative housing cooperating with a metallic shell to commonly define a card receiving space therebetween in a vertical direction;
a plurality of first contacts disposed in the housing in a first row along a transverse direction, which is perpendicular to said vertical direction, with first resilient contacting sections extending into the card receiving space;
a plurality of second contacts disposed in the housing in a second row along the transverse direction with second resilient contacting sections extending into the card receiving space behind the first resilient contacting sections in a front-to-back direction perpendicular to both said vertical direction and said transverse direction; and
an electronic card received in the card receiving space and defining on one surface a plurality of first conductive pads in a third row along said transverse direction and correspondingly contacting the first contacts, respectively, and a plurality of second conductive pads in a fourth row along said transverse direction and behind the first conductive pads in the front-to-back direction and correspondingly contacting the second contacts, respectively; wherein
said second conductive pads include signal pads, at least a voltage pad and grounding pads, and a plurality of spring tangs unitarily extend from the metallic shell into the card receiving space to mechanically and electrically connect the corresponding grounding pads, respectively.

18. The electrical card connector assembly as claimed in claim 17, wherein said metallic shell defines an opening which is large enough to not only allow at least one corresponding spring tang to extending from an edge of said opening and into said opening but also to expose the second resilient contacting section of at least one second contact in the vertical direction.

19. The electrical card connector assembly as claimed in claim 18, wherein the spring tang and the second resilient contacting section of the at least on second contact extend in opposite directions in said opening.

20. The electrical card connector assembly as claimed in claim 17, wherein the electronic card defines a recess in said surface and said second conductive pads are located in the recess, and both said spring tangs and said second resilient contacting sections are located in said recess.
